(19) United States
(12) Patent Application Publication
(10) Pub. No.: US 2026/0082529 A1
(43) Pub. Date: Mar. 19, 2026

(54) SHIELDING SHELL ASSEMBLY, CONNECTOR AND ELECTRONIC PRODUCT

(71) Applicants: Tyco Electronics (Shanghai) Co., Ltd., Shanghai (CN); Tyco Electronics AMP Qingdao Ltd., Qingdao City (CN)

(72) Inventors: Jiefeng (Lear) Zhang, Shanghai (CN); Zhiqiang (Simon) Li, Shanghai (CN); Jinqiang (Jeff) Wang, Qingdao (CN); Guoxiao (Neo) Shen, Shanghai (CN); Wei (David) Zhao, Shanghai (CN); Guibin (Gabby) Lin, Foshan (CN)

(73) Assignees: Tyco Electronics (Shanghai) Co., Ltd., Shanghai (CN); Tyco Electronics AMP Qingdao Ltd., Qingdao City (CN)

(21) Appl. No.: 19/325,874

(22) Filed: Sep. 11, 2025

(30) Foreign Application Priority Data
Sep. 14, 2024 (CN) 202411297913.4

(51) Int. Cl. H05K 9/00; H01L 23/552

(52) U.S. Cl. CPC H05K 9/0049; H10W 42/20

(57) ABSTRACT

A shielding shell assembly includes a shielding shell and a mounting frame. The mounting frame is fixed to an outer side of the shielding shell. The mounting frame has a loading plate pressed against a top surface of a loading frame for a circuit board. The shielding shell is loaded onto the circuit board by the loading plate.

### CROSS-REFERENCE TO RELATED APPLICATION

This application claims the benefit of the filing date under 35 U.S.C. § 119(a)-(d) of Chinese Patent Application No. 202411297913.4, filed on Sep. 14, 2024.

### FIELD OF THE INVENTION

The present invention relates to a shielding shell assembly and, more particularly, to a shielding shell assembly, a connector comprising the shielding shell assembly, and an electronic product comprising the connector.

### BACKGROUND OF THE INVENTION

In order to mount and fix a shielding shell (also referred to as a socket cage) of a connector onto a circuit board, a plurality of pins are typically formed at a bottom of the shielding shell, and a plurality of holes are formed in the circuit board. The plurality of pins on the shielding shell are respectively press-fitted into the plurality of holes in the circuit board. In this typical mounting process, it is necessary to form the plurality of holes in the circuit board. However, forming of holes in the circuit board affects both the wiring of the circuit board and the electrical performance of an entire electronic product.

### SUMMARY OF THE INVENTION

A shielding shell assembly includes a shielding shell and a mounting frame. The mounting frame is fixed to an outer side of the shielding shell. The mounting frame has a loading plate pressed against a top surface of a loading frame for a circuit board. The shielding shell is loaded onto the circuit board by the loading plate.

### BRIEF DESCRIPTION OF DRAWINGS

The invention will now be described by way of example with reference to the accompanying figures, of which:

FIG. 1 is a perspective view of a shielding shell assembly according to an exemplary embodiment;

FIG. 2 is an exploded view of the shielding shell assembly of FIG. 1;

FIG. 3 is a perspective view of a shielding shell assembly according to another exemplary embodiment;

FIG. 4 is an exploded view of the shielding shell assembly of FIG. 3;

FIG. 5 is a top perspective view of a connector according to an exemplary embodiment;

FIG. 6 is a bottom perspective view of the connector of FIG. 5; and

FIG. 7 is a partially enlarged cross-sectional view of an electronic product according to an exemplary embodiment.

### DETAILED DESCRIPTION

Exemplary embodiments of the present disclosure will be described hereinafter in detail with reference to the attached drawings, wherein like reference numerals refer to like elements. The present disclosure may, however, be embodied in many different forms and should not be construed as being limited to the embodiment set forth herein; rather, these embodiments are provided so that the present disclosure will convey the concept of the disclosure to those skilled in the art.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

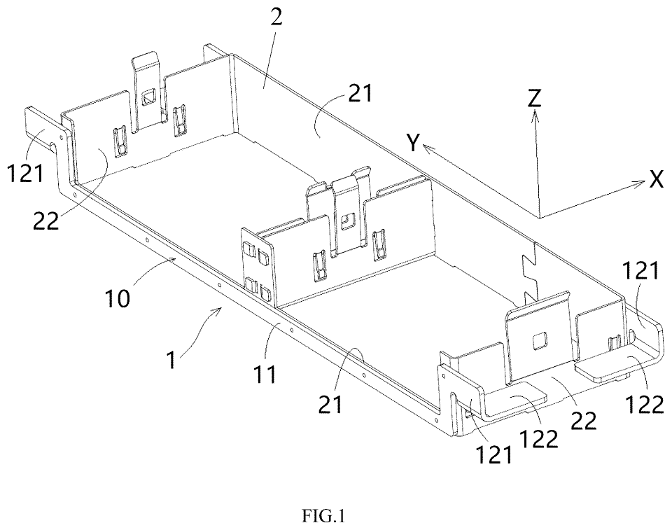

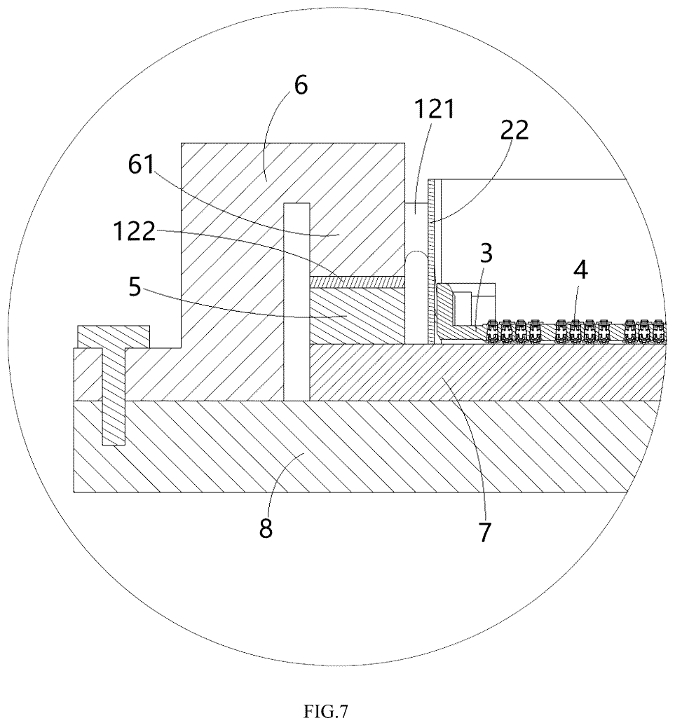

An exemplary embodiment of a shielding shell assembly will now be described with reference to FIGS. 1-2 and 5-7. As shown in FIG. 1, the shielding shell assembly comprises a shielding shell 2 and a mounting frame 1. The mounting frame 1 is fixed to an outer side of the shielding shell 2. The mounting frame 1 has a loading plate 122, as shown in FIGS. 1-2 and 5-7. As shown in FIG. 7, the loading plate 122 is adapted to be pressed against a top surface of a loading frame 5 for a circuit board 7, such that the shielding shell 2 is adapted to be loaded onto the circuit board 7 by the loading plate 122.

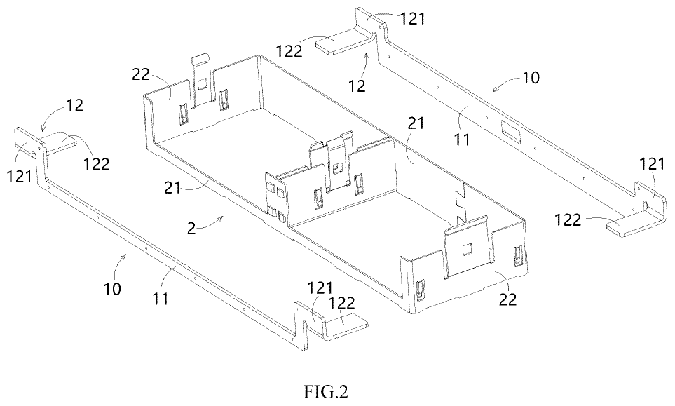

As shown in FIGS. 1-2, the shielding shell 2 has two side walls 21 opposite in a transverse direction X of the shielding shell 2 and two end walls 22 opposite in a longitudinal direction Y of the shielding shell 2. The mounting frame 1 is fixed to outer sides of the two side walls 21 of the shielding shell 2. The mounting frame 1 has two loading plates 122 perpendicular to a height direction Z of the shielding shell 2. As shown in FIG. 1, the two loading plates 122 are respectively adjacent to the two end walls 22 and extend between two sides of the end walls 22.

As shown in FIGS. 1-2 and 5-6, the mounting frame 1 comprises two sub-frames 10 respectively fixed to the outer sides of the two side walls 21 of the shielding shell 2. Each of the sub-frames 10 comprises a side plate portion 11 and two end plate portions 12. The side plate portion 11 is fixed to the outer side of the side wall 21 of the shielding shell 2. The two end plate portions 12 are respectively connected to two ends of the side plate portion 11. As shown in FIG. 2, each of the end plate portions 12 comprises the loading plate 122 and a connecting plate 121. The connecting plate 121 is connected between an end portion of the loading plate 122 and an end portion of the side plate portion 11.

As shown in FIGS. 1-2 and 7, the connecting plate 121 perpendicularly intersects the loading plate 122 and is coplanar with the side plate portion 11, and the connecting plate 121 extends beyond the end wall 22 of the shielding shell 2 in the longitudinal direction Y of the shielding shell 2. The loading plates 122 at one end of each of the two sub-frames 10 are opposite each other in the transverse direction X of the shielding shell 2 and are coplanar with each other, and the loading plates 122 at the other end of each of the two sub-frames 10 are opposite each other in the transverse direction X of the shielding shell 2 and are coplanar with each other.

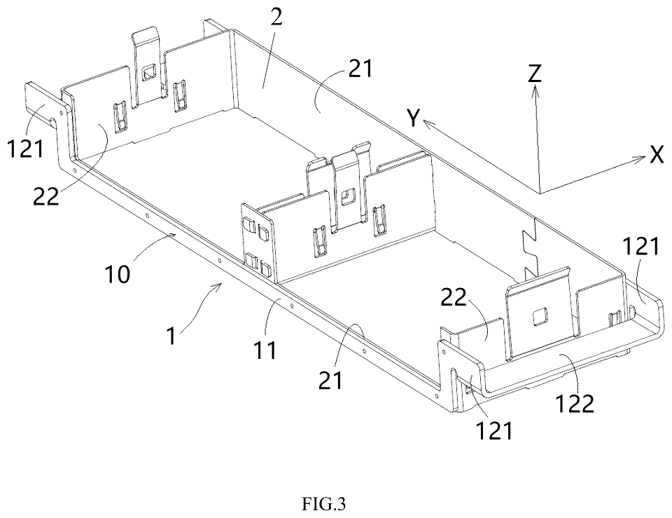

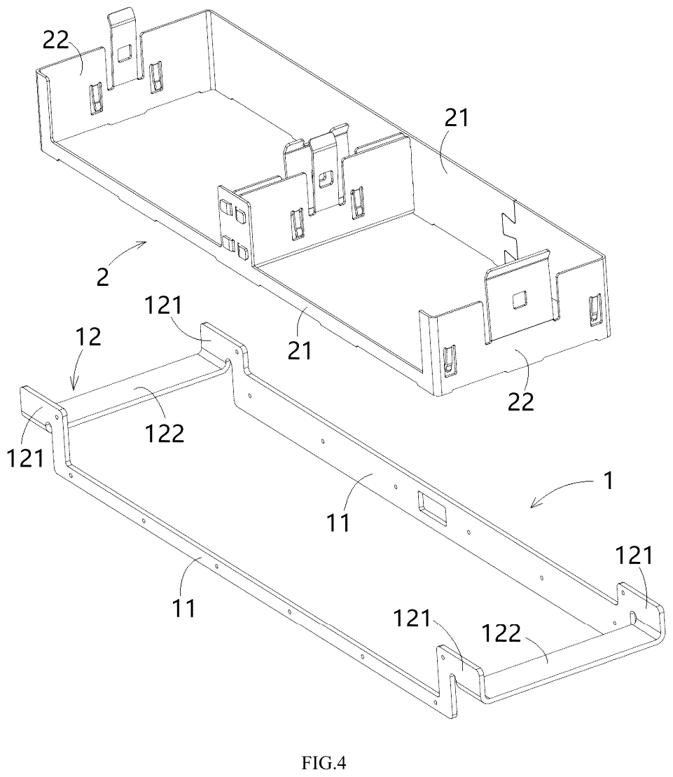

Another exemplary embodiment of a shielding shell assembly will now be described with reference to FIGS. 3-4. The shielding shell assembly according to FIGS. 3-4 differs from the shielding shell assembly of FIGS. 1-2 and 5-6, in that the mounting frame 1 according to FIGS. 3-4 is a one-piece frame. As used hereinafter, the phrase “the embodiments of the shielding shell assemblies” is intended to refer to features that apply to both the embodiment of the shielding shell assembly according to FIGS. 1-2 and 5-7, and the embodiment of the shielding shell assembly according to FIGS. 3-4.

As shown in FIG. 4, the mounting frame 1 comprises two side plate portions 11 and two end plate portions 12. The two side plate portions 11, as shown in FIG. 3, are respectively fixed to the outer sides of the two side walls 21 of the shielding shell 2. One of the two end plate portions 12 is connected between one of the ends of the two side plate portions 11, and the other of the two end plate portions 12 is connected between the other ends of the two side plate portions 11.

As shown in FIGS. 3-4, each of the end plate portions 12 comprises the loading plate 122 and two connecting plates 121. One of the two connecting plates 121 is connected between one end of the loading plate 122 and one end of one of the side plate portions 11, and the other of the two connecting plates 121 is connected between the other end of the loading plate 122 and one end of the other one of the side plate portions 11.

As shown in FIG. 3, one connecting plate 121 perpendicularly intersects one end of the loading plate 122 and is coplanar with one side plate portion 11, and the other connecting plate 121 perpendicularly intersects the other end of the loading plate 122 and is coplanar with the other side plate portion 11.

As shown in FIGS. 2 and 4, the two connecting plates 121 of the end plate portion 12, of the embodiments of the shielding shell assemblies, extend beyond the end wall 22 of the shielding shell 2 in the longitudinal direction Y of the shielding shell 2, and the loading plate 122 of the end plate portion 12, of the embodiments of the shielding shell assemblies, is connected between the two connecting plates 121.

As shown in FIGS. 1-6, the side plate portion 11 of the mounting frame 1, of the embodiments of the shielding shell assemblies, is strip-shaped and is welded, snap-fitted, or riveted to the outer side of the shielding shell 2.

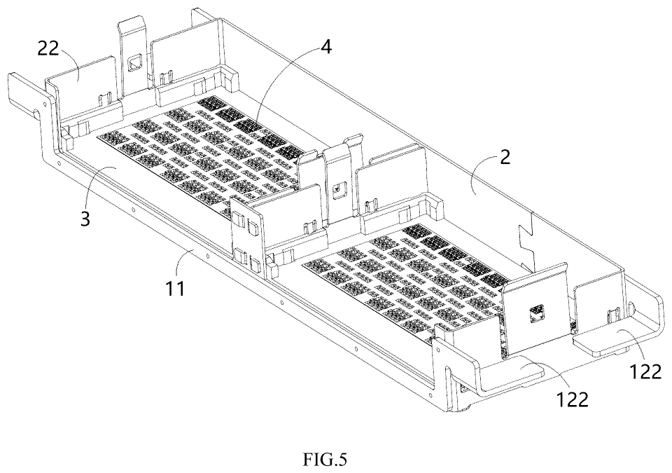

An exemplary embodiment of a connector will now be described with reference to FIGS. 5-7. As shown in FIGS. 5-7, the connector comprises an insulating housing 3, a terminal 4, and one of the embodiments of the shielding shell assemblies. The terminal 4 is disposed in the insulating housing 3. The shielding shell 2 of one of the embodiments of the shielding shell assemblies is sleeved on the insulating housing 3.

An exemplary embodiment of a an electronic product will now be described with reference to FIG. 7. As shown in FIG. 7, the electronic product comprises a circuit board 7, a loading frame 5, and the aforementioned connector. The circuit board 7 is adapted to be mounted on a mounting plate 8. The loading frame 5 is disposed on a top surface around the circuit board 7 and configured to press the circuit board 7 against the mounting plate 8. The connector is mounted on the circuit board 7 and has the terminal 4 electrically connected to the circuit board 7. The loading plate 122 of the shielding shell 2, of one of the embodiments of the shielding shell assemblies, is supported on the top surface of the loading frame 5 and is adapted to be pressed against the loading frame 5, such that the connector is adapted to be loaded onto the circuit board 7 by the loading plate 122.

The electronic product further comprises a chip surface-mounted on the circuit board 7. The terminal 4 of the connector is electrically connected to the chip via a conductive trace on the circuit board 7.

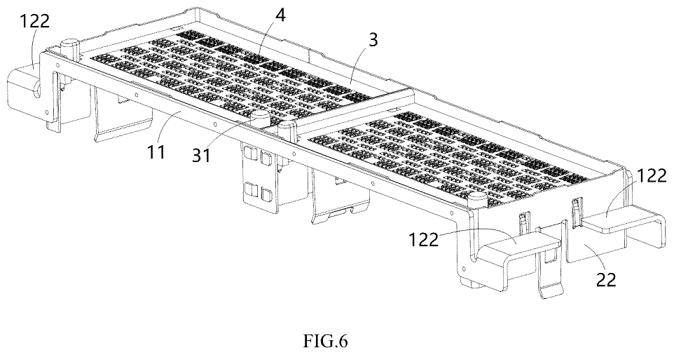

As shown in FIG. 6, a positioning post 31 is formed on a bottom surface of the insulating housing 3 of the connector. The positioning post 31 is adapted to fit with a positioning hole of the circuit board 7 to position the connector on the circuit board 7.

As shown in FIGS. 5-6, the connector comprises a plurality of terminals 4 arranged in an array. As shown in FIG. 7, the plurality of terminals 4 are exposed from a bottom surface of the insulating housing 3 of the connector and are in electrical contact with the circuit board 7. In another exemplary embodiment, the plurality of terminals 4 of the connector are adapted to be in electrical contact with the circuit board 7 under the action of a pressing force applied to the loading plate 122 of one of the embodiments of the shielding shell assemblies.

In another exemplary embodiment, the electronic product further comprises the mounting plate 8 and a loading member 6. As shown in FIG. 7, the loading member 6 is mounted on the mounting plate 8. The loading member 6 has a pressing portion 61 pressing against a top surface of the loading plate 122 of one of the embodiments of the shielding shell assemblies, such that the connector is pressed against and loaded onto the circuit board 7 and the circuit board 7 is pressed against and loaded onto the mounting plate 8.

In the aforementioned exemplary embodiments according to the present invention, the shielding shell 2 of the connector is pressed against and loaded onto the loading frame 5 for the circuit board 7 by the loading plate 122 of one of the embodiments of the shielding shell assemblies. Therefore, in the present invention, it is unnecessary to form pins on the shielding shell 2 and to form holes engaging the pins in the circuit board 7. The present invention does not affect the wiring on the circuit board 7, and can reduce the size of the electronic product and improve the electrical performance of the electronic product.

It should be appreciated for those skilled in this art that the above embodiments are intended to be illustrative, and not restrictive. For example, many modifications may be made to the above embodiments by those skilled in this art, and various features described in different embodiments may be freely combined with each other without conflicting in configuration or principle.

Although several exemplary embodiments have been shown and described, it would be appreciated by those skilled in the art that various changes or modifications may be made in these embodiments without departing from the principles and spirit of the disclosure, the scope of which is defined in the claims and their equivalents.

As used herein, an element recited in the singular and preceded with the word “a” or “an” should be understood as not excluding plural of said elements or steps, unless such exclusion is explicitly stated. Furthermore, references to “one embodiment” of the present invention are not intended to be interpreted as excluding the existence of additional embodiments that also incorporate the recited features. Moreover, unless explicitly stated to the contrary, embodiments “comprising” or “having” an element or a plurality of elements having a particular property may include additional such elements not having that property.

1. A shielding shell assembly, comprising:
a shielding shell; and
a mounting frame fixed to an outer side of the shielding shell, the mounting frame has a loading plate pressed against a top surface of a loading frame for a circuit board, the shielding shell is loaded onto the circuit board by the loading plate.

2. The shielding shell assembly of claim 1, wherein the shielding shell has two side walls opposite each other in a transverse direction of the shielding shell and two end walls opposite each other in a longitudinal direction of the shielding shell, the mounting frame is fixed to outer sides of the two side walls of the shielding shell.

3. The shielding shell assembly of claim 2, wherein the mounting frame has two loading plates perpendicular to a height direction of the shielding shell, the two loading plates are respectively adjacent to the two end walls and extend between two sides of the two end walls.

4. The shielding shell assembly of claim 3, wherein the mounting frame has two sub-frames respectively fixed to the outer sides of the two side walls of the shielding shell, each of the sub-frames has a side plate portion and two end plate portions, the side plate portion is fixed to the outer side of the one of the side walls of the shielding shell, and the two end plate portions are respectively connected to two ends of the side plate portion, each of the end plate portions includes one of the loading plates and a connecting plate connected between an end portion of the loading plate and an end portion of the side plate portion.

5. The shielding shell assembly of claim 4, wherein the connecting plate perpendicularly intersects the loading plate and is coplanar with the side plate portion, and the connecting plate extends beyond the end wall of the shielding shell in the longitudinal direction.

6. The shielding shell assembly of claim 5, wherein the loading plates at one end of each of the two sub-frames are opposite each other in the transverse direction and are coplanar with each other, and the loading plates at the other end of each of the two sub-frames are opposite each other in the transverse direction and are coplanar with each other.

7. The shielding shell assembly of claim 3, wherein the mounting frame is a one-piece frame.

8. The shielding shell assembly of claim 7, wherein the mounting frame has two side plate portions and two end plate portions, the two side plate portions are respectively fixed to the outer sides of the two side walls of the shielding shell, one end plate portion is connected between one end of each of the two side plate portions, and the other end plate portion is connected between the other end of each of the two side plate portions, each of the end plate portions includes the loading plate and two connecting plates, one connecting plate is connected between one end of the loading plate and one end of one of the side plate portions, and the other connecting plate is connected between the other end of the loading plate and one end of the other one of the side plate portions.

9. The shielding shell assembly of claim 8, wherein one connecting plate perpendicularly intersects one end of the loading plate and is coplanar with one side plate portion, and the other connecting plate perpendicularly intersects the other end of the loading plate and is coplanar with the other side plate portion.

10. The shielding shell assembly of claim 8, wherein the two connecting plates of each end plate portion extend beyond the end wall of the shielding shell in the longitudinal direction, and the loading plate of each end plate portion is connected between the two connecting plates.

11. The shielding shell assembly of claim 4, wherein the side plate portion of the mounting frame is strip-shaped and is welded, snap-fitted, or riveted to the outer side of the shielding shell.

12. A connector, comprising:
an insulating housing;
a terminal disposed in the insulating housing; and
a shielding shell assembly including a shielding shell and a mounting frame fixed to an outer side of the shielding shell, the mounting frame has a loading plate pressed against a top surface of a loading frame for a circuit board, the shielding shell is loaded onto the circuit board by the loading plate, the shielding shell is sleeved on the insulating housing.

13. An electronic product, comprising:
a circuit board mounted on a mounting plate;
a loading frame disposed on a top surface around the circuit board and pressing the circuit board against the mounting plate; and
a connector including an insulating housing, a terminal disposed in the insulating housing, and a shielding shell assembly, the shielding shell assembly includes a shielding shell and a mounting frame fixed to an outer side of the shielding shell, the mounting frame has a loading plate pressed against a top surface of the loading frame, the shielding shell is loaded onto the circuit board by the loading plate, the shielding shell is sleeved on the insulating housing, the connector is mounted on the circuit board and the terminal of the connector is electrically connected to the circuit board.

14. The electronic product of claim 13, wherein the loading plate of the shielding shell is supported on the top surface of the loading frame, and the loading plate is pressed against the loading frame, such that the connector is loaded onto the circuit board by the loading plate.

15. The electronic product of claim 14, further comprising a chip surface-mounted on the circuit board, the terminal of the connector is electrically connected to the chip via a conductive trace on the circuit board.

16. The electronic product of claim 14, wherein a positioning post is formed on a bottom surface of the insulating housing of the connector, the positioning post is received in a positioning hole of the circuit board to position the connector on the circuit board.

17. The electronic product of claim 14, wherein the terminal is one of a plurality of terminals arranged in an array in the connector, the plurality of terminals are exposed from a bottom surface of the insulating housing of the connector and are in electrical contact with the circuit board.

18. The electronic product of claim 17, wherein the plurality of terminals of the connector are in electrical contact with the circuit board under an action of a pressing force applied to the loading plate.

19. The electronic product of claim 15, further comprising the mounting plate and a loading member mounted on the mounting plate.

20. The electronic product of claim 19, wherein the loading member has a pressing portion pressing against a top surface of the loading plate, such that the connector is pressed against and loaded onto the circuit board and the circuit board is pressed against and loaded onto the mounting plate.
